(19) United States
(12) Patent Application Publication
(10) Pub. No.: US 2025/0348628 A1
(43) Pub. Date: Nov. 13, 2025

(54) AUTOMATED FRAMEWORK FOR SIMULATED TIME-SERIES DATA GENERATION BASED ON USER-DEFINED CRITERIA

(71) Applicant: The Regents of the University of Michigan, Ann Arbor, MI (US)

(72) Inventors: Arpan KUSARI, Ann Arbor, MI (US); Asma ALMUTAIRI, Baltimore, MD (US)

(21) Appl. No.: 19/204,530

(22) Filed: May 10, 2025

Related U.S. Application Data
(60) Provisional application No. 63/645,591, filed on May 10, 2024.

(51) Int. Cl. G06F 30/15

(52) U.S. Cl. CPC G06F 30/15

(57) ABSTRACT

According to at least one aspect, there is provided an automated, user-configurable simulation data generation system. The system includes: a simulator subsystem configured to execute simulation computer instructions so as to run a simulation; and an automated simulator data processing subsystem configured to execute automated simulator data processing instructions so as to cause data to be prepared for the simulation. When the automated simulator data processing instructions are executed by at least one processor, the automated simulator data processing system: generates simulation input data configured according to a user input and a defined interface, causes the simulation to be executed using the simulation input data in order to generate simulation output data, generates user-interpretable data based on the simulation output data, and provides user access to the user-interpretable data.

### GOVERNMENT FUNDING

This invention was made with government support under 693JJ9-21-D-000016 awarded by the U.S. Department of Transportation. The government has certain rights in the invention.

### BACKGROUND

Advanced Driver-Assistance Systems (ADAS) and Autonomous Vehicles (AVs) rely on the utilization of large-scale, realistic synthetic data as a critical component within their software pipeline to enable secure, efficient, and comfortable navigation through dynamically changing environments. This encompasses the incorporation of high-dimensional sensor data from sensors, such as cameras, LiDAR sensors, and radar sensors, among others, in conjunction with ground truth information across diverse Design Domains such as highway, urban, and rural areas. In particular, this sensor data is integral for the training of neural network models to execute tasks such as object detection, classification, and semantic segmentation, among other applications. Numerous simulators have been devised to facilitate the extraction of synthetic data, some notable examples being Car Learning to Act (CARLA) and Microsoft Airsim. Notably, CARLA has gained widespread popularity due to its provision of various maps, weather conditions, pedestrians, bicyclists, traffic signs and symbols, and vehicle types. However, the use of certain simulation platforms or simulators, such as CARLA, for extracting synthetic data presents challenges for end-users as it lacks a straightforward method for configuring various variables that are often needed to be changed for a successful simulation execution and data collection, subsequently adversely impacting overall data acquisition processes.

### SUMMARY

According to at least one aspect, there is provided an automated, user-configurable simulation data generation system. The system includes: a simulator subsystem configured to execute simulation computer instructions so as to run a simulation; and an automated simulator data processing subsystem configured to execute automated simulator data processing instructions so as to cause data to be prepared for the simulation. When the automated simulator data processing instructions are executed by at least one processor, the automated simulator data processing system: generates simulation input data configured according to a user input and a defined interface, causes the simulation to be executed using the simulation input data in order to generate simulation output data, generates user-interpretable data based on the simulation output data, and provides user access to the user-interpretable data.

According to various embodiments, the method may further include any one of the following features or any technically-feasible combination of some or all of the features:
the simulator system includes at least one processor configured to execute the simulation computer instructions and memory storing the simulation computer instructions;
the automated simulator data processing system includes at least one processor configured to execute the automated simulator data processing instructions and memory storing the automated simulator data processing instructions;
the at least one processor includes one or more first processors and one or more second processors, wherein the automated simulator data processing instructions includes simulator input preparation instructions and simulator output preparation instructions, wherein the simulator input preparation instructions include instructions that, when executed, cause the automated simulator data processing system to generate the simulation input data and cause the simulation to be executed, wherein the simulator output preparation instructions include instructions that, when executed, cause the automated simulator data processing system to generate the user-interpretable data and provide the user access to the user-interpretable data, and wherein the one or more first processors are used to execute the simulator input preparation instructions and the one or more second processors are used to execute the simulator output preparation instructions;
the user input is received via a graphical user interface (GUI) that is used to receive simulation environment characteristics as or as part of the user input the user input, and wherein the simulation environment characteristics specify weather or other environmental aspects of the simulation;
the GUI is further used to receive sensor information as or as part of the user input;
the sensor information is or includes a sensor position of a sensor of a system under testing;
the system under testing is a vehicle system and the sensor position is provided by a user specifying a position on a graphical representation of the vehicle system, and wherein the graphical representation of the vehicle system is a two-dimensional or three-dimensional visual rendering of a vehicle or other portion of the vehicle system;
the user-interpretable data is data generated by transforming the simulation output data in its raw simulator output form into a predetermined structure, form, or aggregation of the simulator output so as to make information indicated by the simulation output data more readily understandable for users;
the user input specifies a number of vehicles, a number of pedestrians, a simulator time length, and simulator capture information such as a simulator frame rate and/or a simulator image width or height;
a user password, passcode, or other secret data is received along with the user input and the simulation is only caused to be executed when the secret data is verified;
sensors of multiple different types are configurable for use in the simulation through a user specifying sensor information for each different sensor type as a part of the user input;
the user input includes one or more user-defined scripts that are to be executed as a part of the simulation;
the user input includes user-defined scenario data that describes a scenario, and wherein the user-defined scenario data is used to automatically generate simulation scenario configuration data used as or for configuring one or more scripts to be executed as a part of the simulation;
the simulation scenario configuration data is generated based on passing the user-defined scenario data as input into a language model; and/or
the language model is a pretrained large language model (LLM).

### BRIEF DESCRIPTION OF THE DRAWINGS

Preferred exemplary embodiments will hereinafter be described in conjunction with the appended drawings, wherein like designations denote like elements, and wherein:

FIG. 1 is a block diagram illustrating a communication system that includes an automated, user-configurable simulation data generation system, according to one embodiment;

FIG. 2 illustrates an exemplary graphical user interface (GUI) as it appears when being operated by a user, according to one embodiment;

FIG. 3 illustrates an exemplary user input object usable with the GUI of FIG. 2, according to one embodiment;

FIG. 4 illustrates an exemplary sensor placement user input screen of the GUI of FIG. 2, according to one embodiment

FIG. 5 is a block diagram illustrating an exemplary user input entry user interface, according to an embodiment;

FIG. 6 is a block diagram illustrating an exemplary user input entry user interface, according to an embodiment; and

FIG. 7 is a flowchart illustrating a method of generating and providing access to user-interpretable simulation output data, according to one embodiment.

### DETAILED DESCRIPTION

Herein is provided a system and method for providing automated execution of a user-configurable simulation in a manner facilitating and enhancing usability of the simulation software or platform, particularly through defining and implementing a user-to-simulation interface that transforms received user input into a simulation input structured according to a predefined interface framework or application programming interface (API). Herein, there is also provided a system and method for generating user-interpretable data based on a simulator output (represented as “simulation output data”) of the simulator. As discussed above, use of many simulation platforms, including driving simulators such as CARLA, include numerous features, configuration options, and other capabilities, resulting in its use becoming arduous and intricate. The usability of said platforms is accordingly deficient in terms of readiness and ease of configuration, setup, and interpretation of results. Embodiments herein aim to provide a system and method addressing said readiness and ease of use deficiencies, as well as other related deficiencies as will become apparent to those skilled in the art in light of the following discussion and accompanying figures.

Conventional methodologies for executing a user-configurable simulation, such as a driving simulation performed by CARLA, for example, have numerous disadvantages, including, for example: (1) a solid understanding of programming concepts is often necessary; (2) a scripting requirement in that every desired task, regardless of its scale, demands scripting, which is often time consuming and requires additional effort; (3) an open-source reliance aspect in that the platform relies on open source community support; (4) outdated documentation; (5) a coding for data storage requirement in that coding for data storage is required and adds complexity; (6) a data interpretation readiness deficiency in that interpreting and/or sharing data with others will involve extra time and effort; and (7) a local storage dependency constraint where there is a dependence on local storage and this oftentimes leads to increased chances of losing or damaging data. According to embodiments, the automated, user-configurable simulation data generation system and method discussed herein overcomes or mitigates effects of these disadvantages, as will be appreciated in light of the following discussion and accompanying figures.

Although the following illustrative embodiments depict and describe an automated, user-configurable simulation data generation system and method for use with driving simulators, such as CARLA, those skilled in the art will appreciate that the disclosed system and method are applicable to other such computer aided simulators in addition to the exemplary driving simulators discussed herein. Accordingly, the simulator is not limited to a driving simulator, unless clearly and expressly stated or asserted otherwise.

According to embodiments, there is provided an automated, user-configurable simulation data generation system having: a simulator subsystem configured to execute simulation computer instructions so as to run a simulation; and an automated simulator data processing subsystem configured to execute automated simulator data processing instructions so as to cause data to be prepared for the simulation. When the automated simulator data processing instructions are executed by at least one processor, the automated simulator data processing system: generates simulation input data configured according to a user input; causes the simulation to be executed using the simulation input data in order to generate simulation output data; generates user-interpretable data based on the simulation output data; and provides user access to the user-interpretable data.

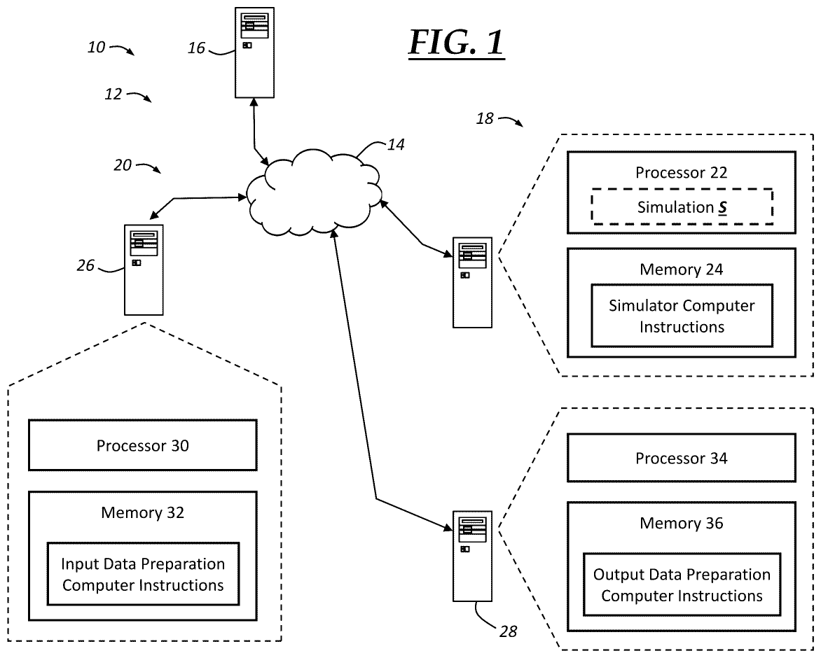

With reference to FIG. 1, there is shown a communication system 10 that includes an automated, user-configurable simulation data generation system 12, an interconnected data network 14, and a user client computer system 16. The automated, user-configurable simulation data generation system 12 is also referred to as an “automated simulation system” 12 and includes: a simulator subsystem 18 configured to execute simulation computer instructions so as to run a simulation; and an automated simulator data processing subsystem 20 configured to execute automated simulator data processing instructions so as to cause data to be prepared for the simulation. The interconnected data network 14 is used to carry out data communications between the automated simulation system 12 and the user client computer system 16, and may correspond to the Internet or other large, interconnected computer and/or carrier network.

The user client computer system 16 is a computer system having at least one computer, comprised of at least one processor and memory storing computer instructions, and the system 16 is configured for providing a user input to the automated simulation system 12 and/or receiving user-interpretable data from the automated simulation system 12. The user client computer system 16 is shown as a desktop computer, but it will be appreciated that the system and method are operable or usable with a variety of different user client computer systems, including those comprised of mobile computers (e.g., smartphones, tablets, laptops), among others. The user client computer system 16 is used to execute one or more processes through use of its at least one processor. The at least one processor of the user client computer system 16 may be any suitable electronic processor, such as: x86/x86-64 processors, such as Intel Core series (e.g., Intel™ Core i3, i5, i7, 19) and AMD Ryzen™ series (e.g., AMD Ryzen™ 3, 5, 7, 9), widely adopted in the personal computing domain; ARM processors, such as Qualcomm Snapdragon™ and Apple MI™ processors, which are popular for mobile and embedded systems; power architecture processors, like IBM Power9, which are oftentimes tailored for server and high-performance computing scenarios; SPARC™ (Oracle™) processors (e.g., SPARC M7, T7), which are oftentimes used for high-end servers; z/Architecture (IBM™) processors (e.g., IBM z15), oftentimes used in mainframe systems; MIPS processors (e.g., MIPS32, MIPS64), which are generally characterized by a reduced instruction set architecture, and are commonly used to address the requirements of embedded systems and networking devices; RISC-V processors (e.g., SiFive™, HiFive™), which is an open-source instruction set architecture, that is commonly used for research, embedded systems, and specialized computing environments; and other like electronic processors, such as graphics processing units (GPUs).

The simulator subsystem 18 configured to execute simulation computer instructions so as to run the simulation S, which may be a driving simulation for testing autonomous vehicles (AVs), for example. The simulator subsystem 18 includes at least one processor 22 and memory 24 storing simulator computer instructions that, when executed by the at least one processor 22, cause the simulation S to be executed or otherwise run. In at least one embodiment, the simulator running the simulation S is a driving simulator, such as CARLA, and is used for testing vehicles. Although the simulator subsystem 18 is shown in FIG. 1 as having a single computer, the simulator subsystem 18 may include a plurality of computers that, together, cause the simulation S to be performed.

The automated simulator data processing subsystem 20 is a computer system that is configured to cause the simulation to be performed and to process output data in order to prepare user-interpretable data for ingestion by a user of the user client computer system 16. The automated simulator data processing subsystem 20 includes an input preparation server 26 and an output preparation server 28. The input preparation server 26 prepares a simulation data input based on user input received from the user client computer system 16, and the output preparation server 28 prepares, based on the simulation output data, user-interpretable data for consumption by the user of the user client computer system 16. Each of the input preparation server 26 and the output preparation server 28 includes at least one processor 30,34 and memory 32,36 storing computer instructions, namely input data preparation computer instructions for the memory 34 and output data preparation computer instructions for the memory 36. Although the illustrated embodiment of FIG. 1 depicts a separate computer and is described as having at least one processor and memory for each of the input preparation server 26 and the output preparation server 28, in other embodiments, the input preparation server 26 and the output preparation server 28 are implemented using one or more shared components, such as one or more shared processors, memory, or other computer components. Moreover, in embodiments, the input preparation server 26 and the output preparation server 28 may be connected via a local network (e.g., local area network (LAN) via ethernet or Wi-Fi), with the user client computer system 16 being connected via a remote or non-local connection. Of course, in other embodiments, other network communication architectures may be used.

The input preparation server 26 is configured to provide a user-to-simulation interface that transforms user input into an input structured according to a predefined interface framework or application programming interface, and this input may also be referred to as a simulation input or simulation input data. The simulation input data is structured according to the simulator executed by the simulation computer instructions, meaning that the simulation input data is specifically generated or prepared according to a predefined programming interface defined by the simulator. The predefined programming interface of the simulator refers to those methods, functions, or other programming code execution calls having a predefined interface for accepting and processing simulator inputs. The simulation input data is input data structured or otherwise configured in a manner that is compatible and in accord with the simulator's predefined programming interface. The input preparation server 26 receives user input provided by a user of the user client computer system 16. This user input may be received via a graphical user interface (GUI) that is presented to the user at the user client computer system 16, such as through a downloadable computer application or a web application.

According to embodiments, the automated simulation system 12 includes a client user application that is usable by the user at the user client computer system 16, and this client user application may be a web application, a mobile application (in the case of a tablet or smartphone being used as the user client computer, for example), or a desktop application. The client user application includes a GUI, at least in embodiments, and this GUI is usable by the user for providing a user input and/or receiving user-interpretable data. In embodiments, namely when the client user application is a web application, the client user application is executed by a web browser and may be hosted at a web domain with a user login so that the user may login and have secure access to the appropriate data for the user.

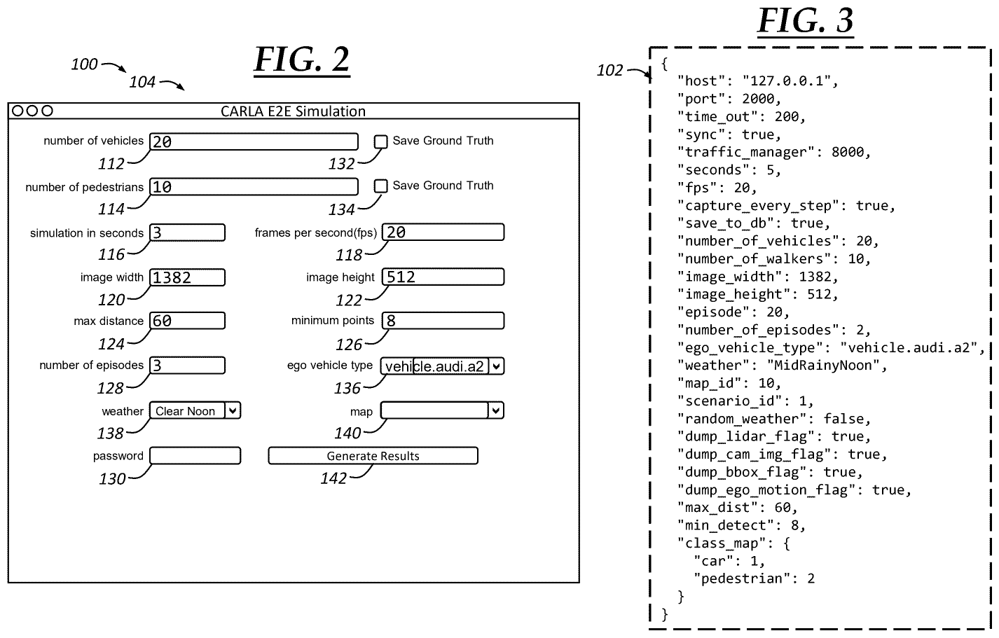

With reference to FIGS. 2 and 3, there is shown an exemplary GUI 100 as it appears on a screen when being operated by a user (FIG. 2) and a user input object 102 (FIG. 3) representing user input data that is input into the GUI 100 by a user. More particularly, FIG. 2 shows an exemplary user input entry screen 104 of the GUI 100. The user input entry screen 104 is a screen of the GUI 100 that depicts input provided by a user and/or provides an input element that is selectable by the user and/or that is able to receive text, image, or other input from the user, which may be specified using one or more computer peripherals or other human-machine interfaces (HMIs). For example, the GUI 100 includes various text entry inputs, checkboxes, selectors, and buttons, specifically: a number of vehicles text entry input 112, a number of pedestrians text entry input 114, a simulation duration text entry input 116, a frame rate text entry input 118, an image width text entry input 120, an image height text entry input 122, a maximum distance text entry input 124, a minimum points text entry input 126, a number of episodes text entry input 128, a password text entry input 130, a vehicle ground truth save checkbox 132, a pedestrian ground truth save checkbox 134, a vehicle type selector 136, a weather selector 138, a map selector 140, and a generate results graphical button 142. Of course, the GUI 100 and the user input entry screen 104 are but one example of a GUI and user input entry screen as the particulars of the GUI and its screens may be adapted to use various different input types and mechanisms, as appreciated by those skilled in the art.

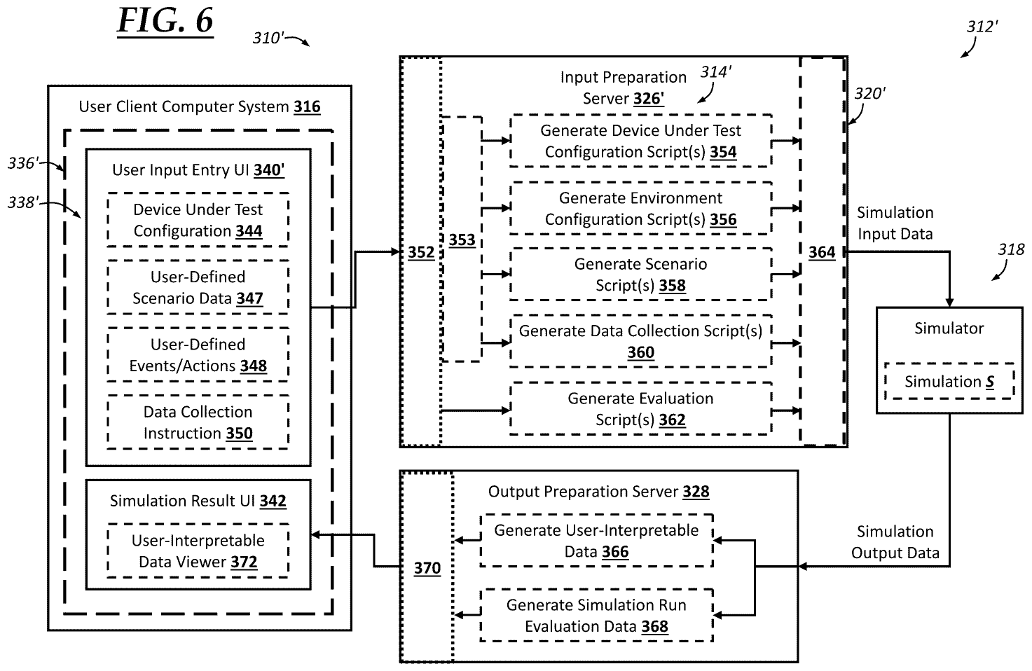

In one embodiment, a language model, such as a large language model (LLM), for example, a pretrained state of the art (SOTA) LLM, such as OpenAI's GPT products (e.g., gpt-4, gpt-3.5-turbo), Google's Gemini™, etc., may be used. In one embodiment, the LLM is executed by a third party service, such as OpenAI via their Enterprise API, or may be executed by an inference server configured, managed, and/or operated by the same party or entity doing so for the system 12. The language model may be a general purpose pretrained model, such as “gpt-4”, or may be fine-tuned version thereof, for example, being fine tuned to the one or more tasks or functions discussed herein. In particular, according to embodiments, the language model is used to generate scenarios for the simulator (e.g., for CARLA), and the language model so configured to generate scenarios for the simulator is referred to herein as a “language model-based scenario generator.” For example, in such embodiments, a user of the user client computer system 16 may provide a text-based input, such as a sentence, phrase, or other text. The language model-based scenario generator is discussed in more detail below, with respect to FIG. 6.

In embodiments, the GUI 100 may further include a scenario input object that enables text input to be entered by a user at the user client computer system 16; for example, an HTML input component of type ‘text’ may be used, and its value may be submitted as a part of the user input object 102 to the automated simulation system 12, as discussed below.

The user input object 102 represents the input that is entered into the GUI 100 by a user, and is structured as a JavaScript Object Notation (JSON) object with attribute names (e.g., “host, “time_out”) and associated values (e.g., “127.0.0.1”, 200). The user input object 102 is prepared by the GUI 100 and sent to the automated simulation system 12, such as through sending the user input object 102 over hypertext transport protocol (HTTP) connection; for example, a POST network using HTTPS call performed over the interconnected data network 14 may be used to securely transmits the user input object 102 to the automated simulation system 12.

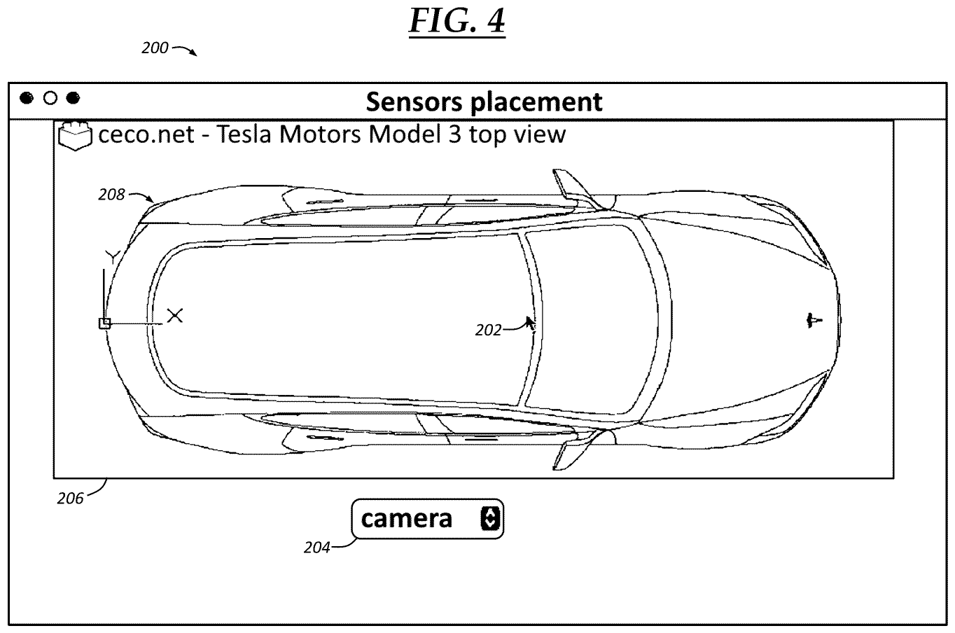

The GUI 100 may include other user input entry screens in addition to the user input entry screen 104, such as a sensor placement user input screen 200, as shown in FIG. 4. According to embodiments, the sensor placement user input screen 200 provides a drag-and-drop interface wherein a user may specify sensor locations and orientations on the vehicle. The sensor placement user input screen 200 is a screen of the GUI 100 and is navigable by a user through use of a cursor 202. The user may use a mouse or other computer peripheral to control the cursor 202, which may be used to select input entry elements, such as a sensor type input entry element 204, and/or to select or otherwise indicate a position or location on a vehicle or other component of the device or system under test, such as a sensor placement position input element 206. The sensor placement position input element 206 is an area on the screen 200 that depicts a graphical representation 208 of the device or system under test, here a vehicle, with the area being selectable at a location within the area corresponding to the device under test graphic 208. The sensor placement position input element 206 includes a two-dimensional graphical representation of the vehicle, and depicts a top view of the vehicle in the illustrated embodiment of FIG. 3. Other views, such as a side view, perspective view, front view, or rear view may also be used and the position of the sensor may be specified in three dimensions through specifying the location in the X-Y plane (using a top or bottom view such as top view in FIG. 3, for example) and in the X-Z plane or Y-Z plane (using a side or front view, for example). In other embodiments, the sensor placement position input element 206 is a three-dimensional rendering of the vehicle and a perspective or point of view is modifiable by the user through use of the cursor 202 or other HMI, for example, enabling the user to select a position in three-dimensional space for the sensor.

In the case of a driving simulation, such as where CARLA is used, the sensors may include one or more of the following, including a combination thereof: cameras, lidar (also referred to as “LiDAR”) sensors, radar sensors, global navigation satellite system (GNSS) (e.g., global positioning system (GPS)) receivers, accelerometers, other inertial measurement units, temperature sensors, and various other sensors included on or used with a vehicle. The GUI 100 supports multiple sensors and collection of sensor data for multiple different types of sensors. A sensor placement user input screen, such as the sensor placement user input screen 200, may be used for specifying a position of each of the sensors and/or other information about the sensor.

The GUI 100 may also be used to present user-interpretable data to a user of the user client computer system 16, such as through providing a text-or character-based table having rows for various events and/or objects of the simulation S with the columns being used for specifying different fields or attributes, values of which are in the cells of each row for the associated event/object. For example, these attribute may include: min_x, min_y, max_x, max_y (coordinates that define the bounding box of a vehicle within a simulation environment); kpt_1_x, kpt_1_y, kpt_1_z (a specific keypoint on a 3D model in a simulation, indicating the keypoint's position in three-dimensional space, such as for use in identifying and/or tracking specific parts of an object for various tasks like collision detection, animation, or analysis); timeGPS (timestamp from GPS data, indicating the specific time at which the GPS data was recorded); X, Y, Z (GPS coordinates usually represent the position of an object in three-dimensional space, with X and Y typically referring to longitude and latitude, and Z often representing altitude or elevation); and sx, sy, sz (length, width, and height, respectively) measurements, respectively, indicating the measurement uncertainty and providing an estimate of the reliability of the position data). Other information, such as vehicle identifiers, other object identifiers, event identifiers, other event/object identifiers (IDs), frame identifiers, object counts, run identifiers (identifying the simulation run), etc. Also, in addition to specific sensor, object, and/or event information, more general information about the simulation run or execution may be provided as well, such as run start time, run end time, actual run duration, run operator, whether the run was successful or failed, another status of run, and test identifiers, for example, as well as simulation and/or user input information, such as vehicles or other objects, weather, map/geography, run target duration, number of sensors (including a breakdown thereof, such as number of cameras, number of lidar, number of radar, number of GPS receivers, for example).

According to at least some embodiments, simulation input data and/or user input data is stored as a saved simulation run configuration for ready recall and use at a later time. Furthermore, the saved simulation run configuration that is stored may be used as a basis for creating one or more derivative or variant simulation run configurations. This may be particularly useful where a user desires to configure a plurality of simulations, each of which may introduce a relatively minor or insubstantial change relative to one another, as is often when running a suite of related experimentation, for example. These derivative or variant simulation run configurations (collectively referred to as “variant simulation run configurations”) may also be stored in memory as saved simulation run configurations for ready recall and use at a later time. This allows a user to readily create a new configuration similar to a previous one without having to redefine or re-enter input for all parameters. In embodiments, the saved simulation run configuration includes one or more predefined scripts that were configured by the user or previous user of the system.

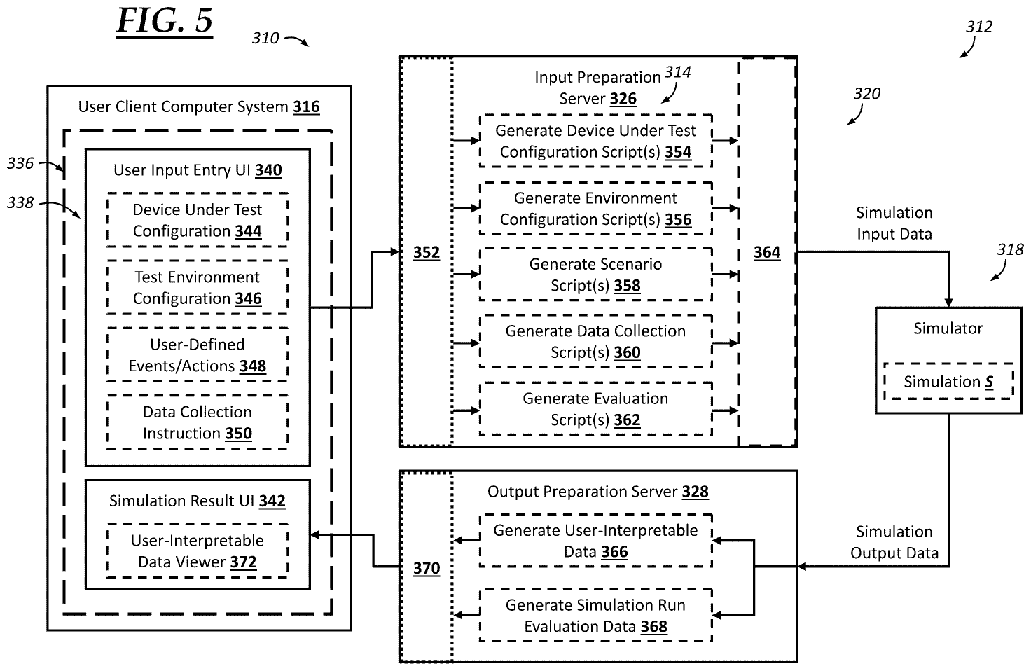

With reference to FIGS. 5 and 6, there are shown a communications system 310, 310′, including an automated simulation system 312, 312′ and a user client computer system 316. It will be appreciated that the components of FIGS. 5 and 6 that have like reference numerals and names to components of FIG. 1 correspond thereto and such discussion above of the communication system 10 and its components is hereby incorporated and attributed to the communications system 310, 310′ of FIGS. 5 and 6.

The automated simulation system 312, 312′ includes a simulator subsystem 318, an input preparation server 326, 326′, and an output preparation server 328 corresponding to the simulator subsystem 18, the input preparation server 26, and the output preparation server 28 of the automated simulation system 12 of FIG. 1, respectively. The automated simulation system 312, 312′ further includes a client user application 336, 336′ that is provided to and executed at the user client computer system 316. The client user application 336, 336′, when executed, causes a GUI 338, 338′ to be presented to the user, such as through displaying graphics on an electronic display screen. The GUI 338, 338′ includes a user input entry user interface 340, 340′ and a simulation result user interface 342. The GUI 338, 338′ may be the GUI 100, for example, discussed above.

The user input entry user interface (UI) 340, 340′ is used for receiving a user input, which is then sent by the client user application 336, 336′ to the input preparation server 314, 314′, such as via an interconnected data network. The user input entry UI 340 of FIG. 5 includes various input or entry portions or elements used for receiving device under test configuration data 344, test environment configuration data 346, user-defined event data 348, and data collection instruction data 350. And, the user input entry UI 340′ of FIG. 6 includes various input or entry portions or elements used for receiving device under test configuration data 344, user-defined scenario data 347, user-defined event data 348, and data collection instruction data 350. The user input entry UI 340, 340′ may correspond to a screen of the GUI 338, 338′, such as the user input entry screen 104 (FIG. 2) and/or the sensor placement user input screen 200 (FIG. 4).

The device under test configuration data 344 is data indicating or specifying a configuration of aspects of the device under test, which is the or a subject of the simulation as it is the device being tested or experimented on through execution of simulation and evaluation of the simulation output data. In one embodiment, such as in the case of a driving simulation, the device under test is an autonomous vehicle (AV) that is having one or more autonomous driving functions tested and/or evaluated. In other embodiments, the device under test is not a vehicle, but another device, component, apparatus, system, or object. The device under test configuration data 344 may specify a vehicle type (see vehicle type selector 136 of FIG. 2), and/or various other information regarding the vehicle, such as a vehicle operating start state (i.e., a predetermined vehicle state used for the start of the simulation), for example.

The test environment configuration data 346 (FIG. 5) is data indicating or specifying a configuration of the environment of the device under test within the simulation S, such as, for example, the number of vehicles (see number of vehicles text entry input 112 of FIG. 2), the number of pedestrians (see number of pedestrians text entry input 114 of FIG. 2), the weather (see weather selector 138 of FIG. 2), and the map (such as a three-dimensional map of a road and surrounding area) (see map selector 140 of FIG. 2).

The user-defined scenario data 347 (FIG. 6) is data entered by a user, such as through use of an HTML input object or uploading of a text file, for example. In at least one embodiment, the text is received via an input object (e.g., HTML input element) and prepared as a part of a JSON object having other user input. The user-defined scenario data 347 is used to describe a scenario for the simulation S to be executed by the simulator, and is generally represented by unstructured text data that is typed using a keyboard or touchscreen, spoken by a user and received at a microphone then processed using speech-to-text techniques, and/or otherwise provided in a tokenized (character-based) representation consumable or transformable to natural language text. The user-defined scenario data 327 is input into a language model-based scenario generator 353 of the input preparation server 326′, which is discussed in more detail below.

The user-defined event data 348 is data indicating or specifying information about an action or event for the simulation S, such as a particular trajectory for one or more vehicles or pedestrians, a change of weather or other environmental attribute, a change in state to the device under test (e.g., a driver input indicating a user turning the steering wheel), etc.

The data collection instruction data 350 is data indicating or specifying information an instruction or request related to collecting of data of the simulation S, such as capturing states at various times. For example, a viewport width and/or height may be specified as data collection instruction data, and this data may further include a sensor sampling rate for one or more sensors within the simulation S. This data 350 may include indications to save ground truth data, which may be obtained based on input received via the vehicle ground truth save checkbox 132 and/or the pedestrian ground truth save checkbox 134. Other information may be collected at the user input entry UI 340, 340′ and sent as part of the user input to the input preparation server 326, 326′ such as a simulation run duration, a number of episodes, etc.

The input preparation server 326, 326′ includes a user-to-simulation interface 352, which is an interface for ingesting the user input from the user client computer system 316. The user-to-simulation interface 352 is implemented using an application programming interface (API) that provides a predetermined structure for providing user input for execution of simulations by the automated simulation system 312, 312′. The user input is then processed by the input preparation server 326, 326′ in order to generate simulation input data, which oftentimes includes various scripts configured according to the simulator being used. For example, in the depicted embodiment, the simulation input data is generated in five parts, including generating device under test configuration scripts or other data 354, environment configuration scripts or other data 356, scenario scripts or other data 358, data collection scripts or other data 360, and evaluation scripts or other data 362. All of this data 354-362 is provided as simulation input data 364 that is structured or otherwise configured according to a predefined programming interface, which is used for defining how the simulator accepts input. The simulation input data 364 is passed as input into the simulator subsystem 318, particularly into the simulator. One or more of the script(s) 354-362 or other data generated at the input preparation server 326 may be stored as a predetermined or saved simulation run configuration.

In FIG. 6, the input preparation system 312′ further includes a language model-based scenario generator 353, which is shown as being coupled between the user-to-simulation interface 352 and certain script generations 354-360, indicating that the custom scenario data generated by the scenario generator 353 may be used to inform the generation of the script(s) 354-360. The user-defined scenario data 347 describes a scenario, and the scenario is used by the language-based scenario generator 353 to automatically generate simulation scenario configuration data, which is data used as or for configuring one or more scripts to be executed as a part of the simulation. For example, according to one embodiment, the language model-based scenario generator is a fine-tuned version of a SOTA pretrained LLM, and is fine-tuned for purposes of transforming unstructured user-defined scenario data into a well-defined scenario, which is represented in the fine-tuned LLM's output by a parsable string of characters representing the script(s) 354-360 and/or portions thereof, or otherwise includes data usable to obtain the appropriate scripts, such as script lookup identifiers provided in the LLM output results that are then used to identify a particular predetermined script.

The output preparation server 328 receives simulation output data from the simulator subsystem 318 as a result of the simulator executing the simulation S. The output preparation server 328 generates user-interpretable data 366 and simulation run evaluation data 368. In embodiments, the simulation run evaluation data 368 includes data analysis metrics, such as statistical summaries, trend analyses, and comparative studies. The simulation run evaluation data 368 is stored in memory and/or provided to the user client computer system 316 as a part of the user interpretable data. This user-interpretable data 366 is then provided via a user interface 370 to the user client computer system 316, particularly the simulation result UI 342 whereat a viewer element, referred to as a viewport or viewer 372, of the UI is used to display the user-interpretable data 366. The simulation run evaluation data 368, such as the data analysis metrics, may be provided with the user-interpretable data 366 or through a separate interface, for example. The simulation run evaluation data 368 may also be presented in a user-interpretable manner so as to also be consider user-interpretable data as well, such as where the data analysis metrics are configured for presentation to a user for facilitating and enhancing understanding and decision-making capabilities.

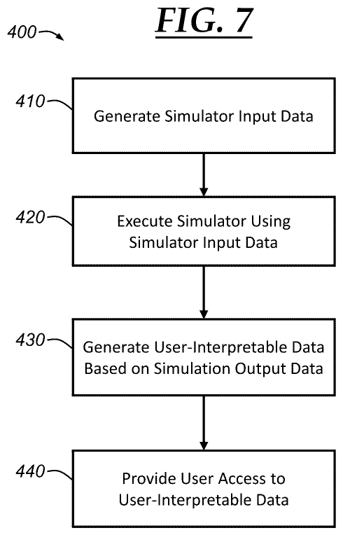

With reference now to FIG. 7, there is shown an embodiment of a method 400 of generating and providing access to user-interpretable simulation output data. The method 400 may be performed by the automated simulation system 12 or the automated simulation system 312, 312′.

The method 400 begins with step 410, wherein simulation input data that is configured according to a user input is generated. The simulation input data is structured or otherwise configured according to a predefined programming interface of the simulator and in a manner so that the desired user simulation operations and configurations (as specified in the user input) are properly executed. The user input is received from the user, and this input may be initially received via a GUI, such as the GUI 100 or GUI 338, 338′. The simulation input data may include various computer code or scripts that are executable by the simulator so as to cause the desired input as indicated by the received user input to be implemented or performed. These scripts or other input data may include the device under test configuration script(s) 354, the environment configuration script(s) 356, the scenario configuration script(s) 358, the data collection script(s) 360, and the evaluation script(s) 362. In embodiments, the language model-based scenario generator 353 is used to generate one or more of the scripts 354-360, such as the environment configuration script(s) 356 and/or the scenario script(s) 358, for example. The method 400 continues to step 420.

In step 420, a simulation is caused to begin execution using the simulation input data in order to generate simulation output data. Here, causing the simulation to be executed using the simulation input data includes operating a simulator computer library according to the predefined programming interface of the simulator so as to initiate a simulation. And, at least according to embodiments, the simulation input data is provided to the simulator subsystem 18, 318 in order to have the simulator execute the simulation according to the user's desires as indicated in the user input. The method 400 continues to step 430.

In step 430, user-interpretable data is generated based on the simulation output data. The simulation S produces data as a result of its execution, including state data for the device under test, environment state data, and other information. This data generated by the simulator as a part or result of the simulation is referred to as simulation output data and may be received as it is generated or all at once when the simulation S is complete. The simulation output data is often in a form that is unprocessed or not readily interpretable by a human user when viewing the data. The output preparation server 28, 328 obtains the simulation output data and then processes this data so as to transform the data into a form that is more readily understandable or otherwise interpretable by the user. This may include processing the simulation output data to obtain aggregate information, to obtain a different structure or organization of the data, or to convert the data into another unit or mode of representation. The simulation output data is processed in real-time as it is received from the simulator so as to provide ready results for the user. The method 400 continues to step 440.

In step 440, user access to the user-interpretable data is provided. This means that access to the user-interpretable data (generated in step 430) is made available to the user, such as through providing the user-interpretable data to the user via the GUI 100, for example, or making the data available via another means, such as through providing access to a database or data store having the user-interpretable data. In embodiments, evaluation of the simulation output data is performed as well, and results of the evaluation may also be provided to the user as user-interpretable data. Quality control data may be generated based on the simulation output data and may be used to identify and rectify anomalies, thereby enhancing the accuracy and reliability of information collected. The evaluation data may be stored in a SQL database or other datastore, and can be transmitted to cloud-based storage for further analysis and integration with other systems, for example. The method 400 ends.

It is to be understood that the foregoing description is of one or more embodiments of the invention. The invention is not limited to the particular embodiment(s) disclosed herein, but rather is defined solely by the claims below. Furthermore, the statements contained in the foregoing description relate to the disclosed embodiment(s) and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art.

As used in this specification and claims, the terms “e.g.,” “for example,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation. In addition, the term “and/or” is to be construed as an inclusive OR. Therefore, for example, the phrase “A, B, and/or C” is to be interpreted as covering all of the following: “A”; “B”; “C”; “A and B”; “A and C”; “B and C”; and “A, B, and C.”

1. An automated, user-configurable simulation data generation system, comprising:
a simulator subsystem configured to execute simulation computer instructions so as to run a simulation; and
an automated simulator data processing subsystem configured to execute automated simulator data processing instructions so as to cause data to be prepared for the simulation,
wherein, when the automated simulator data processing instructions are executed by at least one processor, the automated simulator data processing system:
generates simulation input data configured according to a user input and a defined interface;
causes the simulation to be executed using the simulation input data in order to generate simulation output data;
generates user-interpretable data based on the simulation output data; and
provides user access to the user-interpretable data.

2. The system of claim 1, wherein the simulator system includes at least one processor configured to execute the simulation computer instructions and memory storing the simulation computer instructions.

3. The system of claim 1, wherein the automated simulator data processing system includes at least one processor configured to execute the automated simulator data processing instructions and memory storing the automated simulator data processing instructions.

4. The system of claim 3, wherein the at least one processor includes one or more first processors and one or more second processors, wherein the automated simulator data processing instructions includes simulator input preparation instructions and simulator output preparation instructions, wherein the simulator input preparation instructions include instructions that, when executed, cause the automated simulator data processing system to generate the simulation input data and cause the simulation to be executed, wherein the simulator output preparation instructions include instructions that, when executed, cause the automated simulator data processing system to generate the user-interpretable data and provide the user access to the user-interpretable data, and wherein the one or more first processors are used to execute the simulator input preparation instructions and the one or more second processors are used to execute the simulator output preparation instructions.

5. The system of claim 1, wherein the user input is received via a graphical user interface (GUI) that is used to receive simulation environment characteristics as or as part of the user input the user input, and wherein the simulation environment characteristics specify weather or other environmental aspects of the simulation.

6. The system of claim 5, wherein the GUI is further used to receive sensor information as or as part of the user input.

7. The system of claim 6, wherein the sensor information is or includes a sensor position of a sensor of a system under testing.

8. The system of claim 7, wherein the system under testing is a vehicle system and the sensor position is provided by a user specifying a position on a graphical representation of the vehicle system, and wherein the graphical representation of the vehicle system is a two-dimensional or three-dimensional visual rendering of a vehicle or other portion of the vehicle system.

9. The system of claim 1, wherein the user-interpretable data is data generated by transforming the simulation output data in its raw simulator output form into a predetermined structure, form, or aggregation of the simulator output so as to make information indicated by the simulation output data more readily understandable for users.

10. The system of claim 1, wherein the user input specifies a number of vehicles, a number of pedestrians, a simulator time length, and simulator capture information such as a simulator frame rate and/or a simulator image width or height.

11. The system of claim 1, wherein a user password, passcode, or other secret data is received along with the user input and the simulation is only caused to be executed when the secret data is verified.

12. The system of claim 1, wherein sensors of multiple different types are configurable for use in the simulation through a user specifying sensor information for each different sensor type as a part of the user input.

13. The system of claim 1, wherein the user input includes one or more user-defined scripts that are to be executed as a part of the simulation.

14. The system of claim 1, wherein the user input includes user-defined scenario data that describes a scenario, and wherein the user-defined scenario data is used to automatically generate simulation scenario configuration data used as or for configuring one or more scripts to be executed as a part of the simulation.

15. The system of claim 14, wherein the simulation scenario configuration data is generated based on passing the user-defined scenario data as input into a language model.

16. The system of claim 15, wherein the language model is a pretrained large language model (LLM).
